(19) United States
(12) Patent Application Publication
(10) Pub. No.: US 2026/0160606 A1
(43) Pub. Date: Jun. 11, 2026

(54) THERMOELECTRIC ICING SENSOR

(71) Applicant: "MICROLAB" LIMITED LIABILITY COMPANY, Moscow (RU)

(72) Inventors: Gennady Gyusamovich GROMOV, Moscow (RU); Semen Aleksandrovich GLYAZER, Moscow (RU); Aleksandr Ivanovich MOROZOV, Moscow (RU); Yury Vitalievich ZAKHARTSEV, Moscow (RU)

(21) Appl. No.: 18/706,996

(22) PCT Filed: Oct. 20, 2022
(86) PCT No.: PCT/RU2022/050333

§ 371 Date: May 2, 2024

(30) Foreign Application Priority Data
Nov. 3, 2021 (RU) 2021132214

(51) Int. Cl. G01K 7/02; H10N 10/10; H10N 10/851

(52) U.S. Cl. CPC G01K 7/02; H10N 10/10; H10N 10/851

(57) ABSTRACT

The invention relates to the field of electrical engineering, and more particularly to means for remotely detecting ice formation and determining environmental conditions. A thermoelectric icing sensor comprises a first thermoelectric assembly containing a first thermoelectric element, a first thermoelectric heat flow sensor and a temperature sensor; a second thermoelectric assembly containing a second thermoelectric element and a second thermoelectric heat flow sensor; a thermally conductive plate and a protective casing. The first and second thermoelectric assemblies are mounted spaced apart from one another on a base. Arranged separately on the inner side of the thermally conductive plate, in the gap between the first and second thermoelectric assemblies, is the temperature sensor. The thermoelectric heat flow sensors are connected in series, and the thermoelectric elements are connected to one another. The thermoelectric assemblies, the temperature sensor and the thermally conductive plate are contained within the protective casing, which is open in the region of the outer surface of the thermally conductive plate, forming a channel, the bottom of which is formed by the outer surface of the thermally conductive plate, and the walls of which are formed by the protective casing. The result is that of increasing sensitivity to ice formation or the potential for ice formation, while at the same time increasing the accuracy with which ice formation or the potential for ice formation is determined.

The proposed invention relates to the means of signaling and control and can be used in the icing sensors for the remote detection of icing and determination of environmental conditions that are similar to those for the formation or susceptibility to the formation of icing on various surfaces, such as road surfaces, runways, aircraft surfaces, wind turbines, power lines, etc.

The build-up of ice or conditions for the formation of an ice cover directly affect the safe operation of machinery.

The ice formation on the surface of aircraft makes them more difficult to operate and increases the risks of accidents.

The build-up of ice on power lines increases the rate of accidents and causes frequent outages due to broken wires.

Currently, there are different icing sensors operating on the basis of various direct or indirect methods for determining the presence of icing or susceptibility to the icing.

Mostly, these are icing alarms which, based on various physical principles, determine the presence of ice or the probability of ice formation.

Among icing sensors, a marked advantage belongs to the sensors capable of detecting the actual water-ice phase transformation and the opposite (ice-water) phase transformation.

Such sensors use an integrated Peltier element (thermoelectric cooler) to implement a heating-cooling cycle in the measurement channel. The integrated thermal sensor captures the actual water-ice phase transformation which occurs with the release or absorption of a significant amount of heat at a fixed temperature of such phase transition.

The characteristics of icing to be detected by such sensors include the actual icing or susceptibility to icing, the temperature of the icing, and the intensity of the icing.

A disadvantage of many icing sensors is that they cannot reliably detect all these signs of icing at the same time. This is especially true for such quantitative characteristics as the ice formation temperature and intensity (amount of ice).

Such disadvantages are caused both by indirect methods for determining the occurrence of a phase transition event and by estimation methods for determining the intensity.

For example, a method and system for detecting the probability of ice formation on a vehicle surface are known from the prior art (see U.S. Pat. No. 4,570,881, IPC B64D15/20, published on Feb. 18, 1986). The method involves placing a diaphragm on the vehicle's surface, and alternately cooling and heating the said diaphragm with a Peltier element to temperatures below and above the ambient temperature in accordance with a defined cycle that creates and then melts the ice, if the ambient temperature is near or below the freezing point. In the said cycle, the diaphragm is alternately and repeatedly cooled and heated, and any change in the resonant vibration frequency of the diaphragm is captured. The change in resonance frequency indicates a water-ice phase transition. Therefore, the ice formation is determined qualitatively, without any quantitative interpretation.

A thermoelectric icing sensor is known from the prior art (see RU2534493, IPC B64D15/20, published on Nov. 27, 2014). A known thermoelectric icing sensor comprises a thermoelectric module made in the form of a Peltier element acting as a heat pump and a temperature sensor mounted on the external sensing surface.

Based on a pre-defined algorithm and depending on the ambient temperature and its proximity to the freezing temperature, the Peltier element heats up or cools down the sensing surface. The temperature sensor tracks changes in temperature. If there is ice on the surface or there are conditions for ice formation, the temperature of the sensing surface becomes stable for the period of water-ice phase transition, with the release or absorption of latent heat by the ice formation. A known thermoelectric sensor captures the specified phase transition temperature, thereby identifying the occurrence of ice formation, and the intensity of ice formation is evaluated by measuring the amount of power supply to the heat pump (Peltier element) during this period, as this correlates directly with the heat released or absorbed during the phase transition.

Moreover, the indirect determination of intensity is fraught with large errors, since the power supply capacity of a running Peltier element is highly dependent on variable operating conditions (in particular, ambient temperature, and heat exchange with the environment).

A thermoelectric icing sensor disclosed in utility model patent RU162213, published on May 27, 2016, IPC B64D15/20, is selected as the nearest analog (prototype) of the proposed thermoelectric sensor. A known thermoelectric icing sensor comprises a thermoelectric module in the form of a Peltier element which, in its lower part is connected to a thermoelectric heat flux sensor, while its opposite, upper part forms an external surface sensitive to ice formation and is equipped with a temperature sensor.

A thermoelectric module designed as a Peltier element ensures cyclic heating-cooling of the external sensing surface of the heat flux sensor within the temperature range of ice cover formation.

In case of ice or susceptibility to ice formation on the sensing surface of the upper part, the thermoelectric heat flow sensor captures the release of the latent heat during the ice formation by detecting a signal corresponding to the heat flowing through it, and the temperature sensor captures the ice formation temperature.

A known icing sensor allows to determine the intensity of ice formation by capturing the heat that passes through the integrated heat flux sensor over the ice formation period. This amount of heat at the known specific heat of ice formation allows to determine the amount of ice or water (or their layer thickness in the measurement channel).

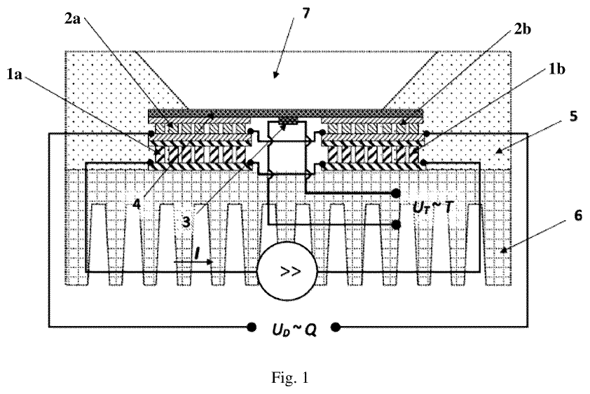

A disadvantage of such icing sensor results from significant errors in determining the ice formation temperature. This is due to the fact that the temperature sensor located directly on the surface of the heat flux sensor above the cooling (or heating) surface of the Peltier element (FIG. 1) inaccurately captures the phase transition temperature. Its intermediate position between the temperature zones, such as the ambient temperature zone and the temperature zone created by the Peltier element, leads to capturing the intermediate temperature at the moment of ice formation. Water and aqueous solutions are characterized by noticeable overcooling before spontaneous crystallization, which means that, at the moment when the crystallization starts, the temperature of the elements in the sensor structure near the crystallization zone is markedly lower than the crystallization temperature.

Therefore, given its intermediate position between the ambient environment and the Peltier element, the temperature sensor captures a temperature below the true temperature of ice crystallization. In particular, this error increases as the ice-water sample on the sensing surface becomes smaller.

To increase the accuracy of measurements in such sensors, some noticeable empirical corrections were made to take into account the parasitic effects of ambient temperature, which reduces the accuracy and precision of obtained results.

The technical problem, which the present invention aims to solve, is to improve the accuracy of measuring the quantitative characteristics when determining the ice formation by a thermoelectric sensor.

The technical result achieved in solving the technical problem consists in increasing the sensitivity to ice formation or susceptibility to ice formation while improving the accuracy in determining the ice formation or susceptibility to its occurrence.

The technical problem is solved, and the technical result is achieved by the fact that the thermoelectric icing sensor comprises a first thermoelectric assembly, a temperature sensor, a second thermoelectric assembly, a thermally conductive plate, a protective casing, and a base. The first thermoelectric assembly comprises a first thermoelectric element and a first thermoelectric heat flux sensor mounted on it, and the second thermoelectric assembly comprises a second thermoelectric element and a second thermoelectric heat flux sensor mounted on it. The first and second thermoelectric assemblies are mounted spaced apart from one another on a base. A thermally conductive plate is mounted on top of the first and second thermoelectric assemblies, and a temperature sensor is separately placed in the gap between the first and second thermoelectric assemblies on the inner side of the thermally conductive plate. The first and second thermoelectric elements are electrically connected to each other, and the first and second thermoelectric heat flux sensors are electrically connected in series to each other. The first and second thermoelectric assemblies, the temperature sensor and the thermally conductive plate are contained within the protective casing, which is open in the region of the thermally conductive plate to form a channel, the bottom of which is formed by the outer side of the thermally conductive plate and the walls are formed by the protective casing.

Also, the technical problem is solved and the technical result is achieved in the following particular embodiments of the thermoelectric sensor.

The thermally conductive plate can be made of metal or thermally conductive ceramics.

The thermoelectric elements may be Peltier elements.

The protective casing may be made of a material with low thermal conductivity, such as a polymeric material with low thermal conductivity.

A thermally conductive plate mounted on the first and second thermoelectric heat flux sensors is made of a material with high thermal conductivity, such as metal or thermally conductive ceramics. This design of thermally conductive plate allows to measure the minimum temperature change in the channel as quickly as possible and, therefore, increases the sensitivity to ice formation or susceptibility to ice formation and the accuracy of determining the ice formation or susceptibility to ice formation.

The placement of the temperature sensor on the inner side of the thermally conductive plate ensures its direct thermal contact with the sample to be measured. Its isolation from thermoelectric assemblies and its position in the gap between them minimizes the temperature effect of these elements on the temperature sensor which, in turn, has a positive effect on the sensitivity to ice formation or susceptibility to it and the accuracy of their determination.

The electrical connection of the thermoelectric elements, both parallel and in series, allows to control them as a single combined thermoelectric element. The electrical connection of thermoelectric heat flux sensors in series allows to sum up their sensitivity and capture the heat flux signal as if it were by a single heat flux sensor. Both of these ensure the coordinated operation of the two assemblies, and hence improve the overall accuracy of determining the ice formation or susceptibility to ice formation.

The presence of two thermoelectric assemblies joined by a thermally conductive plate and a temperature sensor located separately between them enables a more uniform absorption/transfer of thermal energy to the sample on the thermally conductive plate, thereby ensuring a uniform temperature along the entire length of the thermally conductive plate. Thus, a temperature sensor located separately and yet between the assemblies measures a temperature that more accurately corresponds to the temperature of the sample.

Enclosing all elements of the structure located on the base in a protective casing and making such casing from a material with low thermal conductivity allows to ensure protection of the structure against mechanical and thermal impacts from the outside. At the same time, the formation of a channel from the diaphragm and protective casing enables targeted measurement of sample temperature while minimizing external parasitic temperature effects. In other words, this minimizes the effect of any changes in ambient temperature outside the channel and, therefore, ensures better sensitivity to detecting ice formation or susceptibility to ice formation and improved accuracy in determining them.

The present invention is further explained by the following drawings.

FIG. 1 shows the design of the thermoelectric sensor.

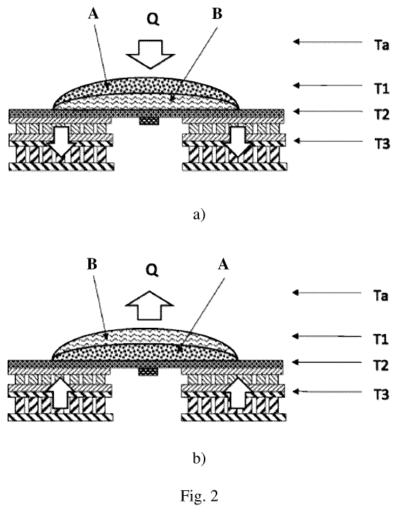

FIG. 2 shows the diagram of cyclic change in the temperature of the thermoelectric icing sensor using a thermoelectric element (a-cooling phase, b-heating phase).

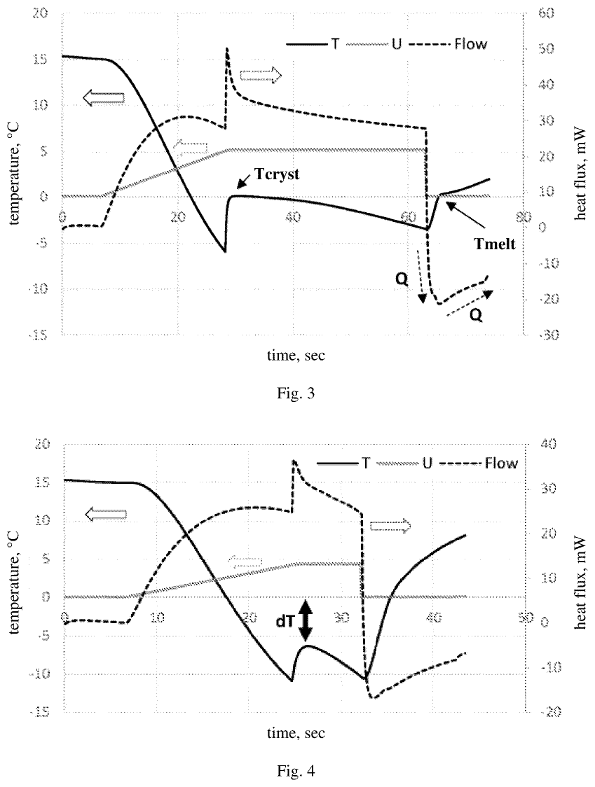

FIG. 3 shows the chart of characteristic changes in temperature and heat flux in the operating icing sensor when there is water in the channel (cooling phase).

FIG. 4 shows the chart of characteristic changes in temperature and heat flux in the prototype of the operating icing sensor when there is water in the channel (cooling phase).

According to this utility model, the thermoelectric sensor is designed to be mounted on any surface where the ice formation is possible.

FIG. 1 schematically shows the structure of a thermoelectric sensor that comprises a first thermoelectric element (1a) and a second thermoelectric element (1b), wherein each thermoelectric element is a thermoelectric module that comprises n-type and p-type semiconductor thermoelements.

On the outer sides of the first (1a) and second (1b) thermoelectric elements, there are the first (2a) and second (2b) thermoelectric heat flux sensors which also comprise n- and p-type semiconductor thermoelements to form two thermoelectric assemblies “thermoelectric element heat flux sensor” (1a-2a and 1b-2b). The first (1a) and second (1b) thermoelectric elements are connected to each other to form an electrical circuit, and the first (2a) and second (2b) thermoelectric heat flux sensors are connected to each other in series to form an electrical circuit. Each “heat flux sensor—thermoelectric element” assembly (“1a-2a” and “1b-2b”) may be connected to each other by any means known to those skilled in the art, for example, by soldering metallized surfaces. On the outer sides of the first (2a) and second (2b) thermoelectric heat flux sensors, there is a thermally conductive plate (4) connecting them.

To improve sensitivity to ice formation, the two thermoelectric assemblies are mounted on the base (6) at a distance from each other to form a gap. A thermally conductive plate (4) is mounted on top of the first and second thermoelectric assembly. On the inner side of the thermally conductive plate (4), a temperature sensor (3) is separately placed in the gap between the first and second thermoelectric assembly. Such mutual arrangement of the structural elements eliminates the temperature effect of both thermoelectric assemblies on the temperature sensor (3) during the temperature measurement. To minimize external mechanical impacts and the influence of changes in ambient temperature, the first (1a) and second (1b) thermoelectric elements, the first (2a) and second (2b) thermoelectric heat flux sensors, the temperature sensor (3) and the thermally conductive plate (4) placed on the base (6) are enclosed in a protective casing (5) made of a material with low thermal conductivity, preferably a polymer material. The use of such materials for protective casing allows to minimize the impact of changes in ambient temperature by obstructing the heat exchange between the external environment and structural elements of the thermoelectric sensor. The protective casing (5) is open in the region of diaphragm (4) to form a channel (7), the bottom of which is formed by the thermally conductive plate (4) and the walls are formed by the protective casing (5). This channel (7) in combination with the thermal insulation of other structural elements by means of the casing (5) enables accurate and timely local measurement of temperature changes. In other words, a change in ambient temperature has a targeted effect exactly in the area where the thermoelectric sensor will be able to measure it as accurately as possible.

The thermoelectric sensor operates as follows.

When the ambient temperature (Ta) is higher than the temperature range of ice formation and there is water (A) at the bottom of the channel with the temperature at the water surface (T1) and the temperature at the diaphragm surface (T2), the thermoelectric elements (1a and 1b) operate as coolers and cool down the thermoelectric heat flux sensors (2a and 2b). The arrows show the heat absorption ‘Q’ by thermoelectric heat flux sensors (FIG. 2a). In this way, the outer surface of the thermally conductive plate (bottom of the channel), which may have a layer of water on it, is cooled down.

Since the liquid is prone to overcooling, the temperature in the channel (7) on the outer sensitive surface of the diaphragm (4) falls, at the beginning of the process, below the ice formation temperature, and there is a characteristic overcooling of the liquid sample. Further, at the maximum overcooling of the sample, there is a spontaneous phase transition of the liquid into the ice with the release of a significant amount of heat, while the temperature of the sample rises to the phase transition temperature (for pure water, this is about 0° C.). The moment of phase transition (ice formation) is detected by both temperature sensor (3) and thermoelectric heat flow sensors (2a and 2b) based on the spike of their output signals (T) and (Flow), respectively (FIG. 3). In this case, the temperature sensor (3) shows the phase transition temperature at the peak of the spike, and the integral of the heat flux emission measured by thermoelectric heat flux sensors during the phase transition time is the heat of crystallization of the liquid.

When the ambient temperature is lower than the temperature range of ice formation and there is ice (B) at the bottom of the channel (7) with the temperature at the ice surface (T1) and the temperature at the diaphragm surface (T2), the thermoelectric elements (1a and 1b) operate as heaters and heat up the thermoelectric heat flux sensors (2a and 2b). The arrows show the heat ‘Q’ generated by the thermoelectric heat flux sensors (FIG. 26). Accordingly, the bottom of the channel (7), which may have a layer of ice on it, is heated up.

As the sample is heated by the thermoelectric elements (1a and 1b), the temperature increases and when the value of phase transition temperature (e.g. for water, this Tₘₑₗₜ=0° C.), the ice begins to melt. The temperature ceases to change in this layer and the heat of ice melting is absorbed. The said heat flows through the thermoelectric heat flux sensors (2a and 2b) and the temperature curve exhibits a characteristic inflection (see FIG. 3, right side). It is related to the fact that a significant amount of heat is absorbed during the complete melting of the sample but, once the melting process is complete, the amount of heat ‘Q’ changes abruptly (the direction of heat flow changes) and this affects the evolution of the temperature curve. This effect can be used to determine the temperature of phase transition (melting) by finding the inflection point based on the calculated mathematical time derivative of the temperature curve.

The continuous monitoring of icing involves successive heating and cooling cycles, along with accurate determination of the icing or susceptibility to the icing of the surface in both phases (crystallization of the liquid and melting of the ice).

FIG. 3 shows typical readings of temperature sensor (3) (T) and thermoelectric heat flow sensors (2a and 2b) (Flow) during uniform cooling by thermoelectric elements (1a and 1b) (where ‘U’ is the supply voltage).

For comparison, FIG. 4 shows a similar measurement cycle and typical readings of the temperature sensor (T) and thermoelectric heat flow sensor (Flow) in the icing sensor made according to the utility model known from RU 162213 (prototype).

The comparison of the charts demonstrates that FIG. 3 displays higher accuracy in the measurement of crystallization temperature than FIG. 4. The accuracy in measuring the temperature of the liquid-ice phase transition obtained with the present utility model is within 0.5° C., which meets the requirements for practical applications. Moreover, the temperature of phase transition can be measured both in the cooling phase (liquid-ice crystallization) and in the heating phase (ice-liquid melting).

The main disadvantage of the prototype is a large error in measuring the phase transition temperature (water crystallization), which is marked in FIG. 4 as ‘dT’, constitutes 5-10° C., and markedly distorts the obtained results. In addition, there is no pronounced inflection of the temperature curve during the heating phase. This inaccuracy is due to the fact that the temperature sensor in the known sensor is located on the sensing surface of the heat flux sensor, directly above the cold surface of the Peltier element. For that reason, the surface temperature of the Peltier element has a strong impact on the temperature sensor readings. In this case, the overcooling that precedes the phase transition will cause all closely spaced structural elements around the temperature sensor (Peltier element surface) to be overcooled relative to the temperature of the crystallizing water in the cooling phase and overheated in the heating phase. Therefore, in the prototype, the temperature sensor indicates, in essence, an intermediate temperature between the phase transition temperature in the channel and the temperature of overcooled or overheated elements in the structure (Peltier element and thermoelectric heat flux sensor).

In the proposed utility model this disadvantage is eliminated by distancing the overcooled surfaces of thermoelectric assemblies from the zone where the temperature of the phase transition is measured. Placing the thermally conductive plate (4) on the thermoelectric assemblies, which thermally conductive plate simultaneously acts as the bottom of the channel (7), enables a more uniform absorption/transfer of thermal energy to the sample on the thermally conductive plate (4), thereby ensuring a uniform temperature along the entire length of the thermally conductive plate. In this case, a temperature sensor (3) located on the inner side of the thermally conductive plate (4) measures the temperature at the bottom of the measuring channel (7) in direct thermal contact with the liquid (ice) sample.

The proposed thermoelectric sensor for detecting icing or susceptibility to the icing on a surface may be widely implemented in the remote detection of icing or susceptibility to the icing on various surfaces.

1. A thermoelectric sensor comprising
a first thermoelectric assembly that has a first thermoelectric element (1a) and a first thermoelectric heat flux sensor (2a) mounted on it, and
a temperature sensor (3),
characterized in that it comprises
a second thermoelectric assembly that has a second thermoelectric element (1b) and a second thermoelectric heat flux sensor (2b) mounted on it
a base (6), on which the first and second thermoelectric assemblies are mounted spaced apart from one another,
a thermally conductive plate (4) mounted on top of the first and second thermoelectric assembly, and
a protective casing (5),
wherein a temperature sensor (3) is separately placed on the inner side of the thermally conductive plate (4) in the gap between the first and second thermoelectric assembly,
wherein the first (2a) and second (2b) thermoelectric elements are electrically connected to each other, and the first (1a) and second (1b) thermoelectric heat flux sensors are electrically connected in series to each other,
wherein the first and second thermoelectric assemblies, the temperature sensor (3) and the thermally conductive plate (4) are contained within the protective casing (5) which is open in the region of the thermally conductive plate to form a channel (7), the bottom of which is formed by the outer side of the thermally conductive plate (4) and the walls are formed by the protective casing (5).

2. A thermoelectric sensor according to claim 1, wherein a thermally conductive plate (4) is made of metal.

3. A thermoelectric sensor according to claim 1, wherein a thermally conductive plate (4) is made of thermally conductive ceramics.

4. A thermoelectric sensor according to claim 1, wherein the thermoelectric elements (1a) and (1b) are Peltier elements.

5. A thermoelectric sensor according to claim 1, wherein a protective casing (5) is made of a material with low thermal conductivity.

6. A thermoelectric sensor according to claim 5, wherein a protective casing (5) is made of polymer material.
